(19) United States
(12) Patent Application Publication
(10) Pub. No.: US 2026/0242927 A1
(43) Pub. Date: Aug. 20, 2026

(54) FILM DEPOSITION METHOD

(71) Applicant: ULVAC, INC., Kanagawa (JP)

(72) Inventors: Naoki Morimoto, Kanagawa (JP); Ryo Takagi, Kanagawa (JP); Shun Manita, Kanagawa (JP)

(73) Assignee: ULVAC, INC., Kanagawa (JP)

(21) Appl. No.: 18/845,583

(22) PCT Filed: Dec. 26, 2023
(86) PCT No.: PCT/JP2023/046570

§ 371 Date: Sep. 10, 2024

(30) Foreign Application Priority Data
May 8, 2023 (JP) 2023-076552

(51) Int. Cl. C23C 14/16; C23C 14/34; C23C 14/54; H10P 50/00; H10P 76/40

(52) U.S. Cl. CPC C23C 14/165; C23C 14/345; C23C 14/542; H10P 76/405; H10P 76/4085; H10P 50/73

(57) ABSTRACT

Provided is a method of depositing a silicon film in which adjustments of film stresses can be made while maintaining optical properties thereof.

Inside a vacuum chamber (1) a target (3) made of silicon and a film-deposition object (Sw) for forming thereon a film are disposed. A sputtering gas is introduced into the vacuum chamber (1) in a vacuum atmosphere. The target is charged with electric power to thereby form, by sputtering, a silicon film (Sf) on a surface of the film-deposition object. At this time, the deposition of the silicon film is performed in two independent steps of a first step for depositing a first silicon film (Sf1) having a columnar structure and a second step for depositing a second silicon film (Sf2) having a columnar structure with a higher film density than that of the first silicon film.

### TECHNICAL FIELD

This invention relates to a film deposition method, and more particularly to a film deposition method for forming a silicon film that can be utilized as a hard mask, and the like.

### BACKGROUND ART

Among the steps for manufacturing semiconductor devices, there is a step for forming a hard mask which restricts the etching range at the time of dry etching an insulation film (e.g., silicon oxide film) formed on a surface of a substrate which is made up of a silicon wafer, the step for forming the hard mask being for the purpose of restricting the etching range at the time of dry-etching the electrical insulation film. As the hard mask there is a case in which a silicon film is used (see, for example, patent document 1). Based on a precondition that this kind of silicon film has a film density exhibiting strong resistance to etching, the silicon film is required to have a predetermined range of film stresses in order to prevent the deformation of the etched shape at the time of dry etching.

On the other hand, when patterning is performed by an exposure apparatus on a resist layer coated on the silicon film, alignment sometimes becomes necessary relative to wiring patterns that have already been formed as a foundation. This kind of positioning (alignment) is ordinarily performed by using laser beams so as to detect the alignment marks that have been formed at predetermined positions of the substrate. Further, as a result of recent trend for finer wiring patterns, laser beams with smaller spot diameters have come to be employed in order to enable positioning with higher precision. Such being the case, it has also come to be required for the above-mentioned silicon film to have also optical properties respectively falling within a range of predetermined refractive index (n-value) and an extinction coefficient (k-value) at predetermined film thicknesses.

In the film deposition of the above-mentioned silicon film, it is considered to employ a sputtering apparatus when productivity, for example, is taken into consideration. In this case, the silicon film is deposited to a predetermined film thickness by: introducing a rare gas into such a vacuum chamber in a vacuum atmosphere as is adapted to receive therein a target made of silicon and a film-deposition object (i.e., an object on which a film is to be deposited or formed) in a manner to face each other; and charging the target with DC electric power having negative potential or AC electric power, thereby sputtering the target so that the silicon film is deposited at a predetermined film thickness. At this time, if adjustments are made to the sputtering conditions such as: the partial pressure of the sputtering gas at the time of film deposition; the electric power to be charged to the target; the bias power to the substrate; and the like, it is generally known that the film stresses or the optical properties can be independently adjusted to predetermined ranges. However, it was not possible, for example, to adjust the film stresses while maintaining the optical properties.

### PRIOR ART DOCUMENTS

### Patent Documents

Patent Document 1: Japanese U.S. Pat. No. 6,952,866

### DISCLOSURE OF THE INVENTION

### Problems to be Solved by the Invention

In view of the above points, this invention has a problem of providing a method of depositing a silicon film in which the adjustments to the film stresses are possible while maintaining the optical properties of the silicon film.

### Means for Solving the Problems

As a result of strenuous efforts and studies, the inventors of this invention have come to obtain the following findings. Namely, at the time of depositing a (single) silicon film at a predetermined film thickness by sputtering a target made of silicon, the desired optical properties (specifically, the refractive index and the extinction coefficient) cannot be maintained even if adjustments are made to the sputtering conditions such as: the partial pressure of the sputtering gas at the time of film deposition; the electric power to be charged to the target; the bias power to the substrate; and the like so as to maintain the film stresses within a predetermined range. Here, the inventors' findings also include the following points. For example, in case there should be required range of values from 4 to 5 as refractive indices (n-value) and range of values from 0.3 to 0.6 as extinction coefficients (k-value), e.g., as the optical properties for the above-mentioned positional alignment, the inventors have obtained the finding that the required optical properties could be more easily obtainable if the silicon film is made to be a film grown in the columnar structure and if the then film density is adjusted according to the changes in the sputtering conditions. Thus, without considering the film stresses, the sputtering conditions under which the optical properties can be maintained at predetermined ranges, were found out first. The silicon film to be deposited under the then sputtering conditions was defined to be the main silicon film. Then, as the foundation layer of the main silicon film, under such sputtering conditions as will give rise to the dense-coarse difference in the film density, specifically by making the film to be grown in the columnar structure and the then film density to be made lower than that of the main silicon film, the inventors' finding was further to the effect that the film stresses could be adjusted while maintaining the optical properties depending on the dense coarse difference in the film density.

In order to solve the above-mentioned problems, this invention is a method of depositing a silicon film, comprising: disposing a target made of silicon and a film-deposition object inside a vacuum chamber; introducing a sputtering gas into the vacuum chamber in a vacuum atmosphere; charging the target with electric power to thereby deposit, by sputtering, the silicon film on a surface of the film-deposition object. In the above-mentioned arrangement, deposition of the silicon film is performed in two independent steps comprising: a first step of depositing a first silicon film having a columnar structure; and a second step of depositing a second silicon film having a columnar structure with a higher film density than the film density of the first silicon film.

According to the above-mentioned arrangement, it has been confirmed that, while maintaining the optical properties, the film stresses could be adjusted depending on the dense coarse difference in film density between the first silicon film and the second silicon film. By the way, during the film deposition, silicon films are deposited also on such parts as deposition preventive plates and the like that are present inside the vacuum chamber. At this time, the surface layer portion will be subjected to deposition of the second silicon film that is high in film density. Therefore, the number of particles that may be kept suspended inside the vacuum chamber may decrease as a consequence of peeling off from the surface layer portion of the above-mentioned parts when deposition of the silicon film was repeated. Consequently, the number of particles that may deposit on a film-deposition object after film deposition can be minimized to the best extent possible. In addition, the following points have been confirmed that: the film deposition can be made with good film distribution on the in-plane of the substrate and further that; the film deposition can be performed without giving rise to the difference in film thickness distribution among the film-deposition objects when film deposition has been performed repeatedly on a plurality of film deposition objects.

In this invention, suppose that a partial pressure of the sputtering gas inside the vacuum chamber in the first step is defined to be a reference partial pressure, then the partial pressure of the sputtering gas in the second step may be made lower than the reference partial pressure. According to this arrangement, by varying the partial pressure of the sputtering gas at the first step and at the second step, the film density of the first silicon film and of the second silicon film can advantageously be varied. At this time, it is advantageously possible to continuously deposit the first silicon film and the second silicon film by adding thereto the dense-coarse difference in the film density within a single vacuum chamber. In this case, the ratio of the partial pressure in the first step to that in the second step may be set to a range from 0.1 to 0.7. If the ratio of the partial pressure is smaller than 0.1, the thin film to be obtained will be, on the one hand, of a thin film of a high density with too high a refractive index (n-value) and too high an extinction coefficient (k-value). On the other hand, if the ratio of the partial pressure becomes larger than 0.7, the thin film will conversely be of a thin film of lower density with too low a refractive index (n-value) and too low an extinction coefficient (k-value).

Further, in this invention, the ratio of the film thickness of the first silicon film to the silicon film may be set to a range from 0.3 to 0.8. According to this arrangement, without varying the optical properties at a predetermined film thickness, the film stresses can advantageously be simply adjusted.

In case bias power is charged to the film-deposition object, while the film is being deposited, by sputtering, on the surface of the film-deposition object, the bias power in the first step and in the second step may be set to a range from 20 W to 100 W. According to this arrangement, the film density of the first silicon film and of the second silicon film may respectively be adjusted, whereby the film stresses can be adjusted over a wide range. By the way, if the bias power is below 20 W, the controllability (trackability) of the power supply will become poor so that the film deposition conditions will become unstable. On the other hand, if the bias power exceeds 100 W, the outcome will become too high density thin films with excessively high refractive indices (n-values) and excessively high extinction coefficients (k-values).

### BRIEF DESCRITION OF DRAWINGS

FIG. 1 is a schematic view showing the arrangement of a sputtering apparatus as a film deposition apparatus for depositing a silicon film, according to this embodiment.

FIG. 2(a) and 2(b) are diagrams to explain film deposition processes of silicon films.

FIG. 3 is a SEM image of a silicon film when deposited under predetermined conditions.

FIG. 4(a), FIG. 4(b) and FIG. 4(c) are graphs showing results of experiments at the time of depositing the silicon films by the deposition method according to these embodiments.

FIG. 5 is a graph showing results of experiments at the time of depositing the silicon films by the deposition method according to these embodiments.

### MODES FOR CARRYING OUT THE INVENTION

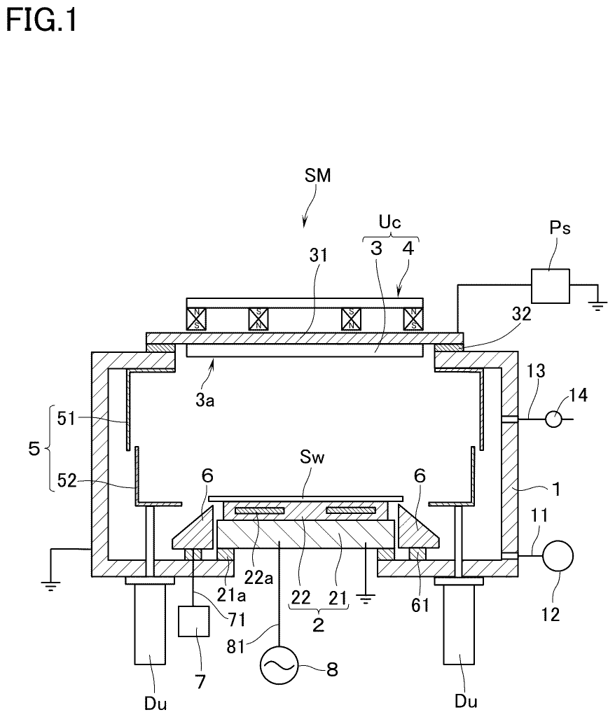

Hereinbelow, with reference to the accompanying drawings and based on an example in: that a film-deposition object has formed on one surface of a silicon wafer a silicon oxide film to a predetermined thickness (hereinafter referred to as “substrate Sw”); that a target is supposed to be made of silicon of a predetermined purity and in; that argon gas is used as a sputtering gas, whereby a silicon film is deposited (formed) on the surface of the substrate Sw according to a sputtering method of this invention. Based on the above-mentioned example, a description will now be made of an embodiment of a method of depositing a silicon film according to this invention. In the following descriptions, terms designating the direction such as up (or upper) and low (or lower) which designate the direction shall be understood to be based on FIG. 1.

With reference to FIG. 1, the reference mark SM shows a magnetron type of sputtering apparatus which is capable of performing the method of depositing a film according to an embodiment of this invention. The sputtering apparatus SM is provided with a vacuum chamber 1 which is grounded. The vacuum chamber 1 has connected thereto a vacuum pump 12 through an exhaust pipe 11 so that the inside of the vacuum chamber 1 can be evacuated into a predetermined pressure (vacuum degree). A side wall of the vacuum chamber 1 has connected thereto a gas pipe 13. The gas pipe 13 has interposed therein a mass flow controller 14, and is communicated with a gas source (not illustrated) of argon gas. In this arrangement, the argon gas whose flow rate is controlled by the mass flow controller 14 can be introduced into the vacuum chamber 1.

The vacuum chamber 1 is provided inside thereof with a stage 2. The stage 2 has: a base 21 which is disposed, through an electrical insulation body 21a, on the inside of the bottom surface of the vacuum chamber 1; and a chuck plate 22 which is made, e.g., of aluminum nitride or of boron nitride, and which is disposed on the base 21. The chuck plate 22 has built therein an electrode 22a for use in an electrostatic chuck. By charging the electrode 22a with electric power from a power supply (not illustrated) for the electrostatic chuck, it is possible to electrostatically suck (hold) a substrate Sw which is mounted with a film-deposition (film-forming) surface facing upward. At this time the substrate Sw will be in an electrically floated state. Although not described in particular with illustration, the chuck plate 22 is provided with a heating and cooling mechanism so that the substrate Sw can be adjusted to a predetermined temperature during film deposition.

Further, the vacuum chamber 1 is provided with a cathode unit Uc. The cathode unit Uc has a target 3, and a magnet unit 4 which is disposed above the target 3 so as to cause a leakage magnetic field in a space between the target 3 and the substrate Sw. On that side of the target 3 which lies opposite to the sputtering surface 3a, there is adhered (or joined) a backing plate 31. It is thus so arranged that, by mounting a peripheral part of the backing plate 31 onto an upper wall of the vacuum chamber 1 through an electrical insulation material 32, the target 3 and the substrate Sw are coaxially positioned opposite to each other inside the vacuum chamber 1. The target 3 has connected thereto an output from the sputtering power supply Ps so that DC power having, e.g., a negative electric potential can be charged in a pulsed manner. The vacuum chamber 1 is provided inside thereof with deposition preventive plates 5 made of stainless steel or aluminum in a manner to enclose the space between the substrate Sw and the target 3 in order to prevent the sputtered particles from getting adhered to the inner walls of the vacuum chamber 1. The deposition preventive plates 5 are made up of: upper deposition preventive plates 51 which are suspended from the upper wall of the vacuum chamber 1; and lower deposition preventive plates 52 which are moveable in a vertical direction by means of a lifting mechanism Du which is provided with a cylinder, a motor, and the like.

The vacuum chamber 1 is provided inside thereof with cylindrical block bodies 6 each having an outline of truncated circular cone positioned around the stage 2. The block bodies 6 are made of metal such as aluminum and copper, and are mounted through electrical insulation bodies 61 which are disposed on the inside of the bottom surface of the vacuum chamber 1. Talking about the state of installing the block bodies 6 in position, the top part of each block body 6 is positioned flush with the upper surface (film-deposition surface) of the substrate Sw which is held by the stage 2, or is positioned below the upper surface. It is thus so arranged that at least part of the outer cylindrical surface faces direct with the plasma atmosphere that is formed inside the vacuum chamber 1. The configuration of the block body 6 need neither be limited to the above nor be needed to be completely enclosing the circumference of the stage 2. For example, a plurality of plate members each having an arcuate outline may be disposed along one and the same circumference, thereby constituting the block body 6. The block body 6 has further connected thereto an output 71 from the DC power supply 7. At the time of film deposition, positive potential is arranged to be appropriately charged by the DC power supply 7 so as to function as an anode. Further, the stage 2 has connected thereto an output 81 from the AC power supply 8 so that, at the time of film deposition, bias power of a predetermined range can be charged to the substrate Sw. Description will be made hereinafter of a film deposition method of this embodiment in which a silicon film is deposited to a predetermined film thickness on the substrate Sw by using the above-mentioned sputtering apparatus SM.

The substrate Sw is mounted on the stage 2 with the film-deposition surface facing upward and, after having electrostatically sucked the substrate Sw, the inside of the vacuum chamber 1 is evacuated. Once the inside of the vacuum chamber 1 has reached a predetermined pressure, a predetermined flow rate of argon gas is introduced, by the control of the mass-flow controller 14, into the vacuum chamber 1 while maintaining a certain effective exhaust speed. Then, DC electric power having a negative electric potential is charged by the sputtering power supply Ps to the target 3 in a pulsed manner. The flow rate of the argon gas at this time is set to a range from 100 sccm to 1000 sccm (the partial pressure of the argon gas inside the vacuum chamber 1 becomes 0.3 Pa to 8.0 Pa). The electric power to be charged is set to a range from 1.0 kW to 5.0 kW. If the flow rate of the argon gas is less than 100 sccm, the outcome will be a high-density thin film with too high a refractive index (n-value) and too high an extinction coefficient (k-value). On the other hand, if the flow rate of the argon gas is above 1000 sccm, the sputtering rate will be too slow, resulting in poor productivity. Still furthermore, if the electric power to be charged is less than 1.0 kW, the sputtering rate will become too late with poor productivity. If the electric power to be charged is above 5.0 kW, on the other hand, the outcome will be a high-density thin film with too high a refractive index (n-value) and too high an extinction coefficient (k-value).

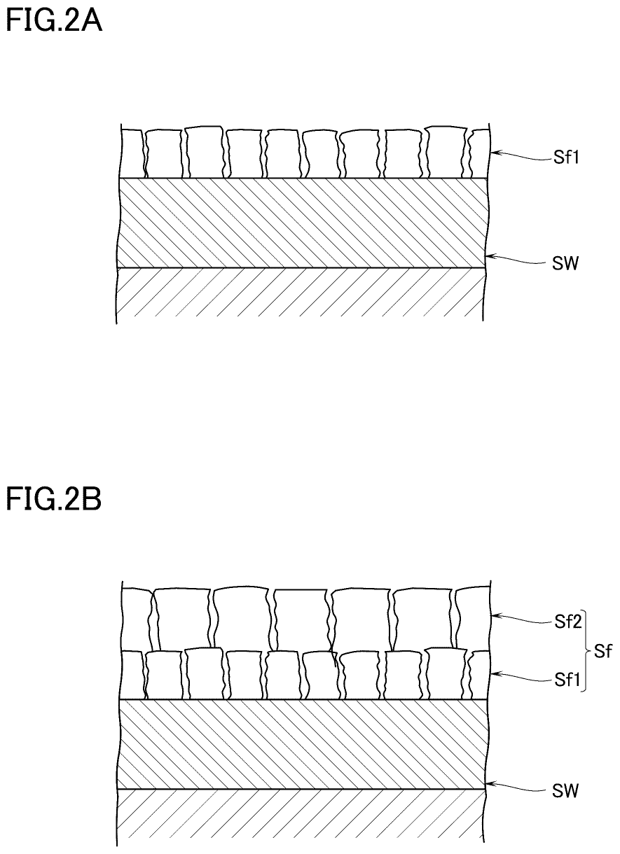

During the film deposition by sputtering the target 3, it may alternatively be so arranged that: positive electric potential (for example, in a range from 0V to 100V, preferably 30V) is charged by the DC power supply 7 to the block body 6; and that bias power (in a range from 20 W to 100 W) is charged by the AC power supply 8 to the substrate Sw. If the bias power is below 20 W, there is a possibility that the controllability of the power supply (tracking property) is poor, whereby the film deposition conditions become unstable. On the other hand, if the bias power exceeds 100 W, the thin film will attain a high density, whereby the refractive index (n-value) and the extinction coefficient (k-value) will become too high. As a result, a plasma atmosphere will be formed in a space between the substrate Sw and the target 3. Due to the ions of the argon gas in the plasma, the target 3 will get sputtered, and sputtered particles will be splashed from the target 3 according to the prescribed cosine law. As shown in FIG. 2(a), there will be deposited (formed) a silicon film in a columnar structure and of a relatively low film density (hereinafter referred to as a “first silicon film Sf1”) (first step). In this case, based on a standard of the film thickness of the silicon film to be deposited from now on, the film thickness of the first silicon film Sf1 will be determined. Based on this film thickness and the sputtering rate depending on the electric power that is charged to the target 3, there will be set the sputtering time when the first silicon film Sf1 is deposited.

Subsequently, when the sputtering time that was set in advance has expired, the mass flow controller 14 is controlled in a state in which the charging of the electric power to the target 3 is maintained as it is, whereby the flow rate of the argon gas is varied. The flow rate of the argon gas at this time is set to a range from 20 sccm to 80 sccm (the partial pressure of the argon gas inside the vacuum chamber 1 will become from 0.08 Pa to 0.2 Pa). In other words, the ratio of the partial pressure of the second step to the partial pressure of the first step is set to a range from 0.1 to 0.7. In this case, if the ratio of the partial pressures is smaller than 0.1, the thin film will become that of a high density with too high a refractive index (n-value) and too high an extinction coefficient (k-value). On the other hand, if the ratio of the partial pressure becomes higher than 0.7, the thin film will become that of a low density, resulting in too low a refractive index (n-value) and too low an extinction coefficient (k-value). Accordingly, as shown in FIG. 2(b), there will be formed (laminated) a silicon film (called hereinafter a “second silicon film Sf2”) which is similarly of columnar structure but with higher film density and “more closely grained” silicon film than those of the first silicon film Sf1 (second step). The sputtering time is set so as to reach the film thickness of the silicon film Sf. By the way, the following points have been confirmed that, if the ratio of the film thickness of the first silicon film Sf1 to that of the silicon film Sf is set to a range from 0.3 to 0.8, the film stresses can be varied without varying the optical properties at a predetermined film thickness. It has also been confirmed that, if the ratio of the film thickness of the first silicon film Sf1 to that of the silicon film Sf is set to a range from 0.3 to 0.7, the optical properties at a predetermined film thickness can still more appropriately be set.

According to the above-mentioned embodiments, it has been confirmed that, while the optical properties were being maintained, the film stresses can be adjusted depending on the dense-coarse difference in film density between the first silicon film Sf1 and the second silicon film Sf2 that were grown in the columnar structure. Further, during the film deposition of the silicon film Sf, silicon films will be deposited also on the inner surfaces of the deposition preventive plates 5. At this time, the second silicon film Sf2 having a high film density will have been deposited on the surface layer portion. As a result, when the deposition of the silicon film Sf is repeated, the number of particles that are peeled off from the surface layer portion of the deposition preventive plates and kept suspended inside the vacuum chamber 1 become small in number. Consequently, the number of the particles that may deposit on the substrate Sw after film deposition will become smaller in number to the best extent possible. In addition, it has been confirmed that the film deposition can be performed at a uniform film thickness distribution on the in-plane of the substrate Sw and that the film deposition can be performed with little or no difference in film thickness distribution among the substrates Sw when film deposition was performed repeatedly on a plurality of substrates Sw.

In order to confirm the above-mentioned effects, the following experiment was carried out by using the above-mentioned sputtering apparatus SM. In this experiment, the substrate Sw was prepared by depositing, on one surface of a silicon wafer, a silicon oxide film to a thickness of 100 nm so that a silicon film was expected to be deposited on the surface of the silicon oxide film to a thickness 50 nm. First, as a preliminary experiment, the electric power to be charged in a pulsed manner to the target 3 was appropriately set to a range of frequency of 150 kHz and from 1 kW to 10 kW, and the flow rate of argon gas was set to a range from 20 sccm to 1000 sccm (the partial pressure of argon gas inside the vacuum chamber at this time was in the range from 0.08 to 8 Pa). Under the above-mentioned conditions silicon films were deposited to a thickness of 25 nm on a plurality of substrates Sw. Such sputtering conditions were confirmed as attaining the refractive index (n-value) in the range from 4 to 5 and the extinction coefficient (k-value) in the range from 0.3 to 0.6. Although not explained by particularly illustrating, the following have been confirmed from the SEM images of the silicon films after film deposition, the confirmation having been made of the following points that the silicon films whose refractive indices and the extinction coefficients both fall within the above-mentioned ranges grew in the columnar structure, and that the film densities varied with the flow rates of the argon gas.

Subsequently, the electric power to be charged to the target 3 in a pulsed manner was: set to a frequency of 150 kHz and 4 kW; the flow rate of the argon gas was adequately varied in a range from 30 sccm to 300 sccm; as the foundation layer the first silicon film Sf1 was deposited on a plurality of substrates Sw at a film thickness of 25nm; thereafter on the surface of the first silicon film Sf1 the second silicon film Sf2 was deposited at a film thickness of 25 nm. The sputtering conditions at the time of depositing the second silicon film Sf2 were set, from among the sputtering conditions that were confirmed in the above-mentioned prior experiments, such that the electric power to be charged to the target 3 was 150 kHz in frequency and 4 kW, and the flow rate of the argon gas was set to 70 sccm (hereinafter the above were defined to be “sputtering conditions 1”). According to the experiments, it was confirmed that: if the flow rate of the argon gas becomes less than 100 sccm, the film stresses (MPa) became smaller; and that the film stresses varied depending on the flow rate of the argon gas. At this time, it was confirmed that the refractive index and the extinction coefficient were maintained within the above-mentioned ranges.

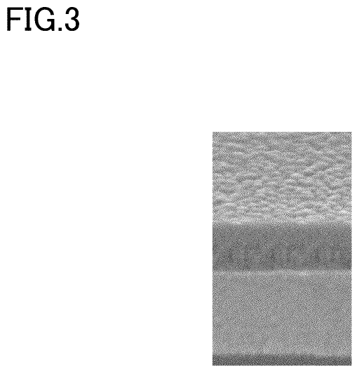

Here, FIG. 3 shows a SEM image in which, as the sputtering conditions at the time of depositing the first silicon film Sf1 were set such that the electric power to be charged to the target 3 in a pulsed manner was at the frequency of 150 kHz and 4 kW, and also the flow rate of argon gas was set at 240 sccm (hereinafter the above were defined to be “sputtering conditions 2”). The SEM image shows the first silicon film Sf1 and the second silicon film Sf2 deposited continuously at a film thickness of 25 nm respectively under the sputtering conditions 1, 2. It can be seen from the above-mentioned SEM image that the film density of the first silicon film Sf1 and the second silicon film Sf2 respectively grew in the columnar structure, and that the film density of the then first silicon film Sf1 is lower than that of the second silicon film Sf2. By the way, it has been confirmed that the similar trend could be seen when the electric power to be charged to the target 3 was varied while the flow rate of the argon gas was kept constant.

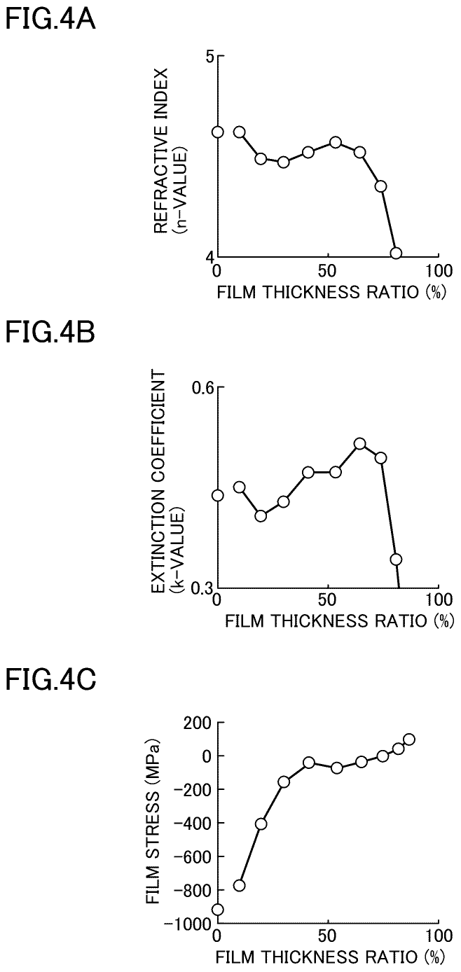

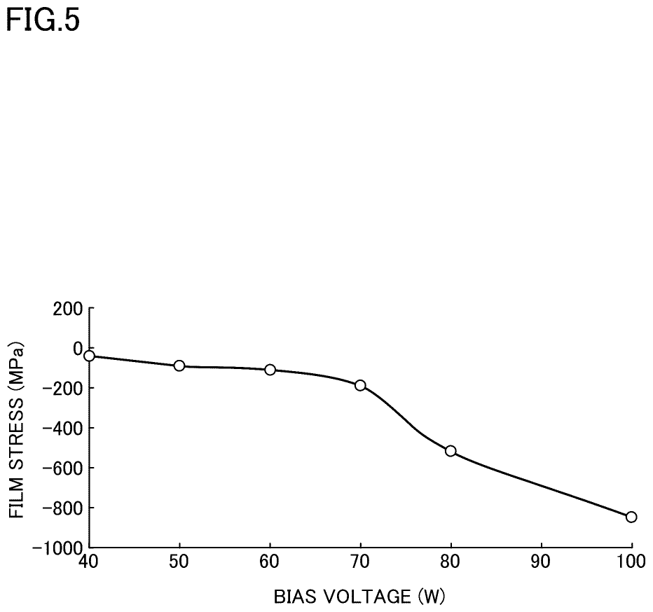

Then, experiments were carried out by varying the sputtering time when the first silicon film Sf1 and the second silicon film Sf2 were deposited under the sputtering conditions 1, 2, so that the ratio of the film thickness of the first silicon film Sf1 to the film thickness (50 nm) of the entire silicon film Sf was varied. According to the experiments, as shown in FIG. 4(a) and FIG. 4(b), it has ben confirmed that, in a range of the ratio of the film thickness from 10% to 80%, the refractive index (n-value) was maintained in a range from 4 to 5 and the extinction coefficient (k-value) was maintained in a range from 0.3 to 0.6, in other words, it can be confirmed that the predetermined optical properties were maintained. Further, as shown in FIG. 4(c), it has been confirmed that, when the film thickness was varied, the film stresses can be varied, especially it was confirmed that, in a film thickness ratio within a range from 30% to 80%, a small film stresses within a range of ±200 MPa could be maintained. Subsequently, at the time of continuously depositing the first silicon film Sf1 and the second silicon film Sf2 at a film thickness of 25 nm respectively under the sputtering conditions 1, 2, the bias power was charged from the AC power supply 8 to the substrate Sw by varying within a range from 40 W to 100 W. According to the above-mentioned arrangement, it can be seen as shown in FIG. 5 that the film stresses varied depending on the bias power while maintaining the predetermined optical properties.

Descriptions have so far been made of the embodiments of this invention, but as long as the technical idea of this invention is not deviated from, various modifications are available. In the above-mentioned embodiments, description was made of silicon films, but it is to be noted that this invention is applicable also to a laminated film in which the film stresses can be adjusted while maintaining the optical properties (e.g., a film with main components of silicon and containing nitrogen and oxygen) by causing the film to have a columnar structure with the dense-coarse difference in film density (e.g., a film with main components of silicon and containing nitrogen and oxygen). In addition, in the above-mentioned embodiments, description was made of an example in which the first step and the second step were continuously performed inside the same vacuum chamber 1. This invention shall, however, not be limited to the above, but such steps may be performed in separate vacuum chambers.

### DESCRIPTION OF REFERENCE MARKS

SM sputtering apparatus
Sw substrate (film-deposition object)
Sf silicon film
Sf1 first silicon film
Sf2 second silicon film
1 vacuum chamber
14 mass flow controller (to adjust partial pressure of sputtering gas)
3 target made of silicon
Ps sputtering power supply

1. A method of depositing a silicon film, comprising:
disposing a target made of silicon and a film-deposition object inside a vacuum chamber;
introducing a sputtering gas into the vacuum chamber in a vacuum atmosphere; charging the target with electric power to thereby deposit, by sputtering, the silicon film on a surface of the film-deposition object;
wherein the deposition of the silicon film is performed in two independent steps comprising: a first step of depositing a first silicon film having a columnar structure; and a second step of depositing a second silicon film having a columnar structure with a higher film density than the film density of the first silicon film.

2. The method of depositing a silicon film according to claim 1, suppose that a partial pressure of the sputtering gas inside the vacuum chamber in the first step is defined to be a reference partial pressure, then the partial pressure of the sputtering gas in the second step is made lower than the reference partial pressure.

3. The method of depositing a silicon film according to claim 1, wherein a ratio of the film thickness of the first silicon film to the silicon film is set to a range from 0.3 to 0.8.

4. The method of depositing a film according to claim 1 in which, while the film is being deposited, by sputtering, on the surface of the film-deposition object, bias power is charged to the film-deposition object,
wherein the bias power in the first step and in the second step is set to a range from 20 W to 100 W.
